(19) United States
(12) Patent Application Publication
(10) Pub. No.: US 2023/0185526 A1
(43) Pub. Date: Jun. 15, 2023

(54) CONVERTER FOR CONVERTING DATA TYPE, CHIP, ELECTRONIC DEVICE, AND METHOD FOR CONVERTING DATA TYPE

(71) Applicant: Anhui Cambricon Information Technology Co., Ltd., Hefei (CN)

(72) Inventors: Yao ZHANG, Hefei (CN); Shaoli LIU, Hefei (CN)

(21) Appl. No.: 17/619,816

(22) PCT Filed: Oct. 22, 2020
(86) PCT No.: PCT/CN2020/122950

§ 371 Date: Dec. 16, 2021

(30) Foreign Application Priority Data
Oct. 25, 2019 (CN) 201911025769.8

(51) Int. Cl. G06F 5/01

(52) U.S. Cl. CPC G06F 5/01

(57) ABSTRACT

The present disclosure relates to a converter for data type conversion, a method for data type conversion, an integrated circuit chip, and a calculation apparatus, where the calculation apparatus may be included in a combined processing apparatus, where the combined processing apparatus may further include a general interconnection interface and other processing apparatus. The calculation apparatus interacts with other processing apparatus to jointly complete a calculation operation specified by a user. The combined processing apparatus may further include a storage apparatus. The storage apparatus is connected to the calculation apparatus and other processing apparatus, respectively. The storage apparatus is used for storing data of the calculation apparatus and other processing apparatus. Solutions of the present disclosure may be widely applied to various data type conversion applications.

### CROSS REFERENCE OF RELATED APPLICATION

The present disclosure claims priority to: Chinese Patent Application No. 201911025769.8 with the title of “Converter for Converting Data Type, Chip, Electronic Device, and Method for Converting Data Type” filed on Oct. 25, 2019. The content of the aforementioned application is herein incorporated by reference in its entirety.

### TECHNICAL FIELD

The present disclosure relates to the technical filed of data processing, and more specifically, the present disclosure relates to data type conversion.

### BACKGROUND

For a traditional computation unit, when an instruction (a computation unit) is implemented, there is generally only a mutual conversion between a fixed-precision floating-point number and an integer number, and a data type conversion function is single. In an artificial intelligence (AI) chip, the number of data type conversion instructions (“conversion number” for short) that are performed is greater than that of a traditional processing unit, and requirements of computer programmers for the data type conversion function have increased significantly. Therefore, a larger number of software calculations may make weaknesses such as low computation efficiency, large memory access overheads, high calculation power consumption of data type conversion implemented through software become more prominent, and a computation speed may become a performance bottleneck of an entire processor core.

Simultaneously, a traditional computation unit implemented through the instruction is implemented with a single function, and if the processor core is required to implement a new data type conversion function, according to the added new function, a logic expression (such as a logic expression function and a logic expression circuit) is required to be added according to a multiplication principle. As such, scalability of the traditional computation unit is poor. Once new function requirements appear, an area of the computation unit in the chip may be increased multiple times, and there may be a lot of repeated calculation logic, which may affect overall performance of the processor.

For example, if there are M types of input data and N types of output data, there are M*N commonly-needed data conversion paths. Therefore, a corresponding circuit design may become relatively complex, power consumption may become relatively high, and every time a new data type appears, a converter may be required to be redesigned, which may increase workloads and reduce production efficiency.

Therefore, a traditional method for the data type conversion performs poorly in the artificial intelligence chip, and a traditional implementation method may not be referred to implement the computation unit in the artificial intelligence chip.

### SUMMARY

One purpose of the present disclosure is to overcome the deficit of low data conversion efficiency and poor scalability in existing technologies.

A first aspect of the present disclosure provides a converter for data type conversion, including: a first conversion stage configured to receive first type data and descriptive information about the first type data and second type data and according to the descriptive information, convert the first type data into an intermediate result; and a second conversion stage configured to convert the intermediate result into the second type data.

A second aspect of the present disclosure provides a chip including the converter above.

A third aspect of the present disclosure provides an electronic device including the chip above.

A fourth aspect of the present disclosure provides a method for data type conversion, including: receiving first type data and descriptive information about the first type data and second type data and according to the descriptive information, converting the first type data into an intermediate result; and converting the intermediate result into the second type data.

A fifth aspect of the present disclosure provides an electronic device, including: one or a plurality of processors; and a memory, where the memory stores computer-executable instructions, and when the computer-executable instructions are executed by the one or the plurality of processors, the electronic device performs the above-mentioned method.

A sixth aspect of the present disclosure provides a computer-readable storage medium, including computer-executable instructions, where, when the computer-executable instructions are executed by one or a plurality of processors, the above-mentioned method is performed.

At least one of beneficial effects of solutions of the present disclosure lies in improving efficiency of the data type conversion in the artificial intelligence chip, reducing computation loads, and decreasing required circuit areas.

### BRIEF DESCRIPTION OF DRAWINGS

By reading the following detailed description with reference to drawings, the above-mentioned and other objects, features and technical effects of exemplary implementations of the present disclosure will become easier to understand. In the drawings, several implementations of the present disclosure are shown in an exemplary but not restrictive manner, and the same or corresponding reference numerals indicate the same or corresponding parts of the implementations.

FIG. 1 shows a converter for data type conversion according to a first aspect of the present disclosure.

FIG. 2 shows a flowchart of a method for data type conversion according to another aspect of the present disclosure.

FIG. 3 shows a schematic block diagram of a first conversion stage L1 according to an implementation of the present disclosure.

FIG. 4a shows a specific structure of a first computation unit C1 and a data structure of an intermediate result according to an implementation of the present disclosure.

FIG. 4b shows a specific structure of a first computation unit C1 and a data structure of an intermediate result according to another implementation of the present disclosure.

FIG. 5a shows a schematic block diagram of an absolute value calculation circuit C11 according to an implementation of the present disclosure.

FIG. 5b shows a schematic block diagram of an absolute value calculation circuit C11 according to another implementation of the present disclosure.

FIG. 6 shows a schematic block diagram of a second conversion stage L2 according to an implementation of the present disclosure.

FIG. 7a shows a schematic block diagram of a pre-output calculation unit P2 according to an implementation of the present disclosure.

FIG. 7b shows a schematic block diagram of a pre-output calculation unit P2 according to another implementation of the present disclosure.

FIG. 8 shows a schematic structural diagram of a data recovery unit R2 according to an implementation of the present disclosure.

FIG. 9a shows a schematic block diagram of a pre-output processing circuit R21 according to an implementation of the present disclosure.

FIG. 9b shows a schematic block diagram of a pre-output processing circuit R21 according to another implementation of the present disclosure.

FIG. 10 shows a structural diagram of a combined processing apparatus according to an embodiment of the present disclosure.

FIG. 11 is a schematic structural diagram of a board card according to an embodiment of the present disclosure.

### DETAILED DESCRIPTION

Technical solutions in embodiments of the present disclosure will be described clearly and completely hereinafter with reference to drawings in the embodiments of the present disclosure. Obviously, embodiments to be described are merely some rather than all embodiments of the present disclosure. All other embodiments obtained by those skilled in the art based on the embodiments of the present disclosure without creative efforts shall fall within the protection scope of the present disclosure.

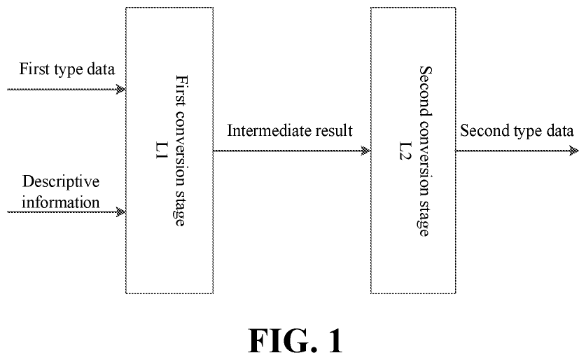

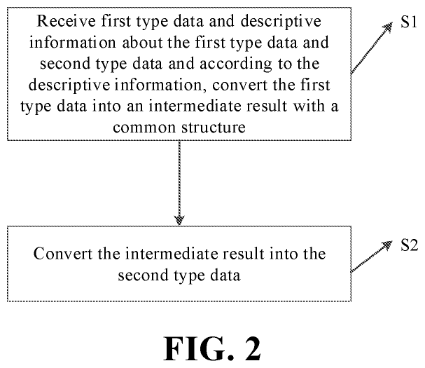

FIG. 1 shows a converter for data type conversion according to a first aspect of the present disclosure. FIG. 2 shows a flowchart of a method for data type conversion according to another aspect of the present disclosure.

As shown in FIG. 1, the converter may include: a first conversion stage L1 configured to receive first type data and descriptive information about the first type data and second type data and according to the descriptive information, convert the first type data into an intermediate result; and a second conversion stage L2 configured to convert the intermediate result into the second type data.

As shown in FIG. 2, the method of the present disclosure may include: a first operation S1, where the first type data and the descriptive information about the first type data and the second type data may be received and according to the descriptive information, the first type data may be converted into the intermediate result; and a second operation S2, where the intermediate result may be converted into the second type data.

It is required to be understood that the aforementioned “first type data” may be original first type data, or may be first type data that is converted, concatenated, and split; in other words, deformations of the first type data in each phrase may also be included in the scope of the first type data.

In the present disclosure, when the type of data is converted, the data may be converted into the intermediate result, and the intermediate result is applicable to all types of data. The intermediate result may efficiently represent the converted data (such as the aforementioned first type data) and may be converted into any type of data that is required (such as the aforementioned second type data). In other words, for all types of data, the intermediate result has a common content and/or structure, and therefore, the data may be converted into other types of data through the intermediate result.

The beneficial effects brought by converting the first type data into the intermediate result and then converting the intermediate result into the second type data include but are not limited to the followings: in a traditional hardware structure, if there are M types of input data and N types of output data, it is required to design an individual circuit for each conversion, and therefore, the complexity of the circuit is approximately M*N, which may greatly increase the workload of circuit design and increase the area of the circuit, thereby further bringing adverse effects such as increased power consumption and an increased cost. However, based on technical solutions of the present disclosure, in a data type conversion with the same number of data types, the complexity of the circuit is only about M+N, which may greatly reduce the complexity of circuit design and reduce the area of the circuit, thereby further decreasing the power consumption of the circuit and saving the cost.

The number of bits of the aforementioned first type data and the number of bits of the aforementioned second type data may be a plurality of cases, for example, 1 bit, 2 bits, 4 bits, 8 bits, 16 bits, 32 bits, and the like. However, in the present disclosure, the number of processing bits (such as the bit width of a register, the bit width of a memory, and the bit width of a bus) of the converter that is adopted may be other numbers of bits, for example, 32 bits. Therefore, according to an implementation of the present disclosure, the first conversion stage L1 may be further configured to determine the number of first type data received and concatenate the first type data to form first concatenation data, and according to the descriptive information, the first conversion stage L1 may convert the first concatenation data into the intermediate result.

For example, if the number of bits of input data is 8 bits and the number of bits of output data is 8 bits, while the number of processing bits (such as the bit width of the register) of the converter is 32 bits, 4 pieces of input data may be received simultaneously at one time, which means that the 4 pieces of input data may be concatenated to form a piece of 32-bit data.

However, if the number of bits of input data is 8 bits and the number of bits of output data is 16 bits, while the number of processing bits of the converter is 32 bits, 2 pieces of input data may be received simultaneously at one time, which means that the 2 pieces of input data may be concatenated to form the piece of 32-bit data. In this case, 2 pieces of 8-bit data may be expanded to 2 pieces of 16-bit data, and then 2 pieces of 16-bit data formed after expanding may be concatenated together.

For another example, if the number of bits of input data is 16 bits and the number of bits of output data is 8 bits, while the number of processing bits of the converter is 32 bits, the 2 pieces of input data may be received simultaneously at one time, which means that the 2 pieces of input data may be concatenated to form the piece of 32-bit data. In this case, the 2 pieces of 16-bit data may include information about 2 pieces of 8-bit output data.

According to an implementation of the present disclosure, the number of first type data received may be determined by dividing the number of bits of data with the highest number of bits in the first type data and the second type data by the number of processing bits of the converter.

For example, if two 8-bit hexadecimal numbers such as 81 and 82 are input and two 16-bit numbers are output, two pieces of data may be received at one time. In an embodiment of the present disclosure, the binary representation of the hexadecimal number 81 may be expressed as “1000 0001”, and the binary representation of the hexadecimal number 82 may be expressed as “1000 0010”. These two binary representations may be expanded to two 16-bit numbers such as “xxxx xxxx 1000 0001” and “yyyy yyyy 1000 0010”. Actual data of an 8-bit number is placed on the low eight bits of the 16-bit number, and the high bits of the 16-bit number are filled with 0 or other specified numbers (here, the numbers are represented by x). The concatenated data may be expressed as 00008182, whose binary representation may be expressed as “xxxx xxxx yyyy yyyy 1000 0001 1000 0010”. In other words, for 32-bit concatenated data, first input data “81” may occupy the low eight bits (0-7), and second input data “82” may occupy the intermediate eight bits (8-15). The high bits of the 32-bit number (16-31) may be filled with x and y, where x and y may be set according to actual situations, and the x and y may be the same or different. The following will give a detailed explanation.

It is required to be understood that the above-mentioned concatenation method is only an example, and those skilled in the art may set the concatenated data with a required format according to needs. For example, a first piece of data received may be placed on the low sixteen bits of the 32-bit concatenated data, and a second piece of data received may be placed on the high sixteen bits of the 32-bit concatenated data. Still taking the above-mentioned hexadecimal numbers such as 81 and 82 as examples for explanation, concatenated data format may further be, for example, xxxx xxxx 1000 0001 yyyy yyyy 1000 0010, where x and y may be the same or different.

According to another implementation of the present disclosure, a preset first fixed value may be used for concatenation. For example, the first fixed value may be 2 or other numbers.

Through a concatenation operation shown in the above-mentioned implementation, throughput of the data may be increased and processing efficiency may be improved. Of course, those skilled in the art may understand that the above-mentioned data concatenation is not necessarily required, but preferred. For example, if the number of bits of at least one of the input data and the output data is the same as the number of bits processed by the converter, the concatenation is not required; additionally, other specified formats (for example, a manner of marking significant bits may be adopted; in other words, some of bits may be specified as the significant bits in advance, and some of bits may be specified as invalid bits in advance) may be used, so that even if the number of bits of the at least one of the input data and the output data is different from the number of bits processed by the converter, the concatenation is also not required. For example, if the number of bits of the input data is 8 bits, and the number of bits of the output data is 16 bits, and the number of bits of the register is 32 bits, 8-bit input data may be directly expanded to 32-bit data (for example, by adding 0 to specific bits of original 8-bit input data), and then when the data is output, the 32-bit data may be restored to 16-bit data.

The above describes the case that the number of bits of the first type data is less than the number of bits of the register, and in another case, if the number of bits of the input data is greater than the number of processing bits of the converter, for example, if the number of bits of the input data is 64 bits and the number of processing bits of the converter is 32 bits, the following processing may be operated.

One processing method is to truncate 64-bit data, reserve 32-bit data required, discard other pieces of 32-bit data, and process 32-bit data reserved. This method may cause certain data loss and errors.

According to another implementation of the present disclosure, the first conversion stage L1 may be further configured to determine the number of to-be-split first type data received and split the first type data to split data with the same number, and according to the descriptive information, the first conversion stage L1 may convert the split data into the intermediate result.

In this implementation, the 64-bit data may be split into two pieces of 32-bit data, and two pieces of 32-bit data that are split may be processed, and finally two pieces of data that are output may be concatenated to further form output data that is required.

According to an implementation of the present disclosure, the number of to-be-split first type data received may be determined by: dividing the number of processing bits of the converter by the number of bits of data with the highest number of bits in the first type data and the second type data.

For example, if the number of bits of the input data is 64 bits, and the number of bits of the output data is 64 bits, and the number of bits of the register is 32 bits, the input data may be split into the two pieces of 32-bit data; after processing, in an output terminal, the two pieces of 32-bit data may be re-concatenated to further form 64-bit output data.

For another example, if the number of bits of the input data is 64 bits, and the number of bits of the output data is 16 bits, and the number of bits of the register is 32 bits, the input data may be split into the two pieces of 32-bit data; after processing, in the output terminal, significant data parts may be truncated from the two pieces of 32-bit data and may be re-concatenated to form 16-bit output data.

For another example, if the number of bits of the input data is 16 bits, and the number of bits of the output data is 64 bits, the 16-bit input data may be expanded to the two pieces of 32-bit data, where one of the two pieces of 32-bit data includes significant information, and the other one includes invalid information (for example, all bits are 0), and when the data is output, the two pieces of 32-bit data may be concatenated to form the 64-bit output data.

According to another implementation of the present disclosure, a preset second fixed value may be used for splitting. For example, the fixed value may be set as 2 or other numbers.

Splitting and concatenating data is beneficial to align timing in the input data and the output data and avoid or reduce extra design of a timing control part in the circuit; additionally, this implementation is beneficial for data parallel processing and improvement of resource utilization.

Corresponding splitting and concatenation functions may be added to the above-mentioned first conversion stage L1 and the above-mentioned second conversion stage L2. The functions may be implemented in the form of software and/or hardware.

It may be shown that the present disclosure does not limit the number of bits of the input, the number of bits of the output and the number of bits of the converter (for example, the register), and through methods such as data splitting and data concatenation, the present disclosure may process data with any number of bits.

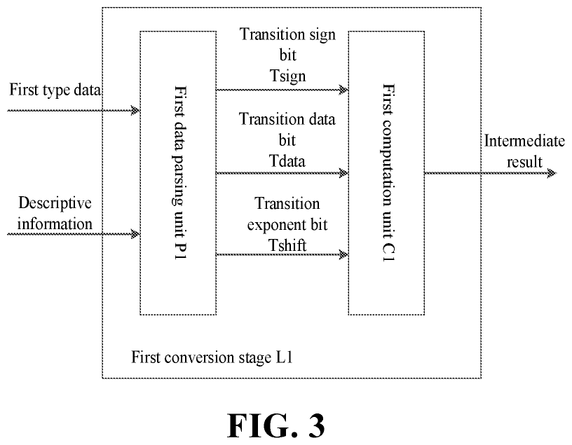

FIG. 3 shows a schematic block diagram of a first converter L1 according to an implementation of the present disclosure.

As shown in FIG. 3, the first conversion stage L1 may include a first data parsing unit P1 and a first computation unit C1.

The first data parsing unit P1 may be configured to generate a transition sign bit Tsign, a transition data bit Tdata, and a transition exponent bit Tshift according to the first type data and the descriptive information. The first computation unit C1 may be configured to generate the intermediate result according to the transition sign bit Tsign, the transition data bit Tdata, and the transition exponent bit Tshift.

The descriptive information may be input to the first data parsing unit P1 manually or in the form of a file or a signal.

According to an implementation of the present disclosure, the above-mentioned descriptive information may include: first descriptive information configured to describe a data type of the first type data and a first exponent bit of the first type data; and second descriptive information configured to describe a data type of the second type data and a second exponent bit of the second type data.

The data type described in the above-mentioned first descriptive information and the above-mentioned second descriptive information may be a plurality of data types, which include but are not limited to an FIX4, an FIXE, an FIX16, an FIX32, an UFIX8, an UFIX16, an UFIX32, an FP16, an FP32, a BFLOAT, and any other existing or self definition data type. It is required to be understood that here only takes the highest 32 bits as an example for explanation, and for 64 bits or other higher bits, a larger number of data types may be included.

Additionally, in this implementation, the first exponent bit that indicates a shift value of the first type data and the second exponent bit that indicates a shift value of the second type data may further be received by the first data parsing unit P1 separately, and then a difference between the first exponent bit and the second exponent bit may be calculated by the P1.

Or, according to another implementation of the present disclosure, the descriptive information may include the first data type of the first type data, the second data type of the second type data, and a difference exponent bit, where the difference exponent bit may be configured to indicate a difference between the first exponent bit of the first type data and the second exponent bit of the second type data.

Different from the previous implementation that the difference exponent bit is calculated by the first data parsing unit P1, in this implementation, the difference exponent bit may be directly input to the first data parsing unit P1 without a subsequent calculation.

It is required to be explained that the “difference” described above, in addition to indicating a size of shift, also indicates the direction of shift. The difference described in the present disclosure may be the first exponent bit minus the second exponent bit, or the second exponent bit minus the first exponent bit. For those skilled in the art, the above description is clear and therefore, no repeated description will not be presented here.

If the difference exponent bit is calculated by the first data parsing unit P1 or is received directly, the transition exponent bit Tshift may be calculated according to the different exponent bit, and the transition exponent bit Tshift is an equivalence of the different exponent bit.

Although the descriptive information and the data are described as two different message carriers in the above, it is required to be understood that there may not be a clear boundary between the descriptive information and the data in practice. For example, if both the first type data and the second type data are Fix-type, the shift value of the first type data and the shift value of the second type data may be indicated in separate descriptive information, and a difference data bit may be calculated according to the two shift values. However, if the first type data is, for example, Float-type, since Float-type data itself includes a first shift value, the P1 may extract the first shift value from the first type data. Therefore, the first type data and first descriptive information thereof, and the second type data and descriptive information thereof may be mixed together, or independent.

It is required to be understood that here, a term “equivalence” indicates that two terms may be the same substantially, but different in form. For example, for an 8-bit number 0000 0001, if the number is converted into 0000 0000 0000 0001, in essence, the converted number is another representation manner of the previous 8-bit number, but the number and the converted number may not be exactly the same. Additionally, it is required to be understood that, in addition to the change of the number of bits, different representations such as a complement, a shift code, a binary, a decimal, hexadecimal of a number are also within the scope of “equivalence” described in the present disclosure. In other words, as long as significant information has not been discarded, any form of change may be regarded as the equivalence.

For example, if the first type data is Float-type, and the second type data is Fix-type, the second shift value extracted from Float-type data may be represented in the form of the shift code, and the shift value for describing Fix-type data may be represented in the form of an original code. At this time, for calculating a difference between the two shift values, the two shift values may be required to be uniformly converted into the same code type and then a difference calculation may be performed. The two shift values may be uniformly converted into the shift code, the original code, the complement, or other types of code. The present disclosure will not describe the conversion of the code type in detail.

According to an implementation of the present disclosure, the descriptive information may further include a rounding type, where the rounding type may include at least one of the followings: a TO_ZERO, an OFF_ZERO, an UP, a DOWN, a ROUNDING_OFF_ZERO, a ROUNDING_TO_EVEN, and a random rounding.

The TO_ZERO represents rounding toward a zero; in other words, the TO_ZERO represents rounding toward a smaller absolute value. The OFF_ZERO represents rounding away from a zero; in other words, the OFF_ZERO represents rounding toward a greater absolute value. The UP represents rounding toward a positive infinity. The DOWN represents rounding toward a negative infinity. The ROUNDING_OFF_ZERO represents rounding up and rounding down. The ROUNDING_TO_EVEN represents that on a basis of rounding up and rounding down, exactly half of the values is rounded to an even number.

It is required to be understood that the above-mentioned rounding type is only exemplary, and those skilled in the art may set various expected rounding types.

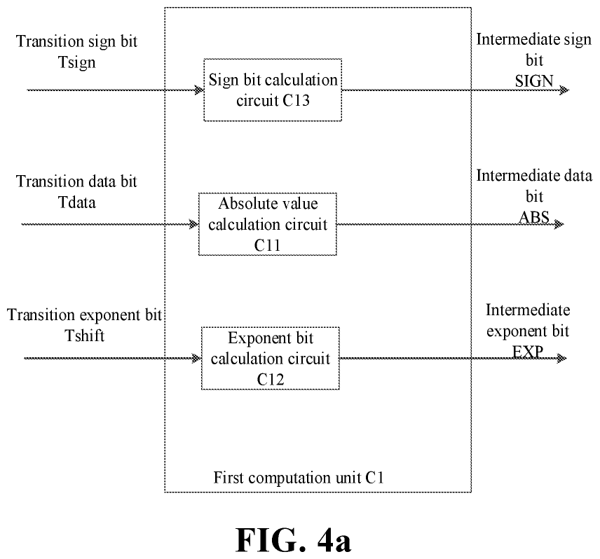

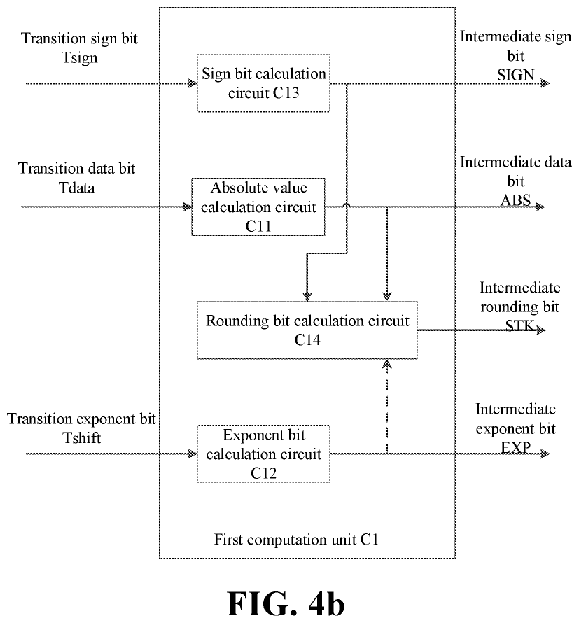

FIG. 4a shows a specific structure of a first computation unit Cl and a data structure of an intermediate result according to an implementation of the present disclosure.

According to an implementation of the present disclosure, the intermediate result may be divided into an intermediate data bit ABS, an intermediate sign bit SIGN, and an intermediate exponent bit EXP. The following describes how to obtain the intermediate result according to the transition exponent bit Tshift, the transition sign bit Tsign, and the transition data bit Tdata in detail. In other words, all pieces of input data may be converted into intermediate data with a common structure.

As shown in FIG. 4a, the first computation unit C1 may include: an absolute value calculation circuit C11 configured to calculate the intermediate data bit ABS according to the transition data bit Tdata.

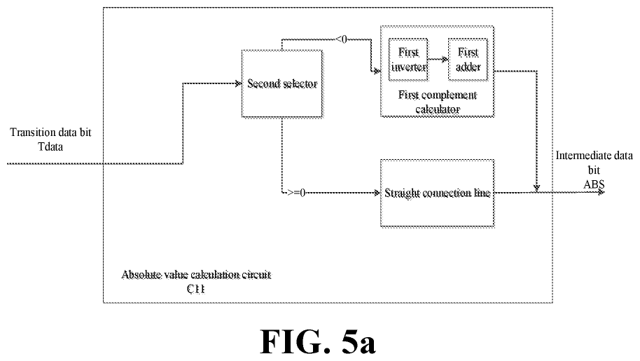

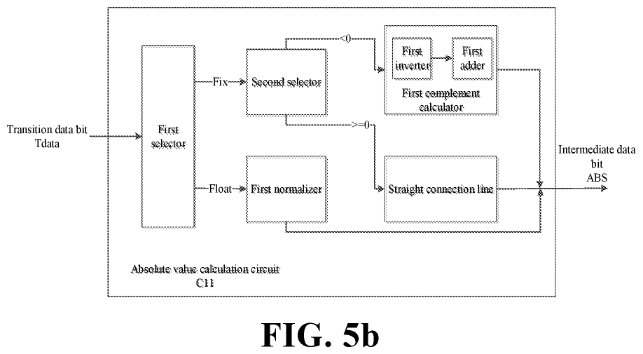

FIG. 5a shows a schematic block diagram of an absolute value calculation circuit C11 according to an implementation of the present disclosure.

As shown in FIG. 5a, the absolute value calculation circuit C11 may include a second selector configured to judge whether the transition data bit Tdata is less than 0; a first complement calculator configured to calculate a complement of the transition data bit and take the complement of the transition data bit as the intermediate data bit ABS if the transition data bit Tdata is less than 0, otherwise, take the transition data bit Tdata as the intermediate data bit ABS. Calculating the complement is actually to invert other bits, other than a sign bit, and add 1. Therefore, the first complement calculator may include a first inverter and a first adder. However, if the transition data bit Tdata is greater than or equal to 0 (in other words, the transition data bit Tdata is not negative), the intermediate data bit ABS is equal to the transition data bit Tdata.

FIG. 5b shows a schematic block diagram of an absolute value calculation circuit C11 according to another implementation of the present disclosure.

As shown in FIG. 5b, the absolute value calculation circuit C11 may further include a first selector and a first normalizer. The first selector may be configured to receive the transition data bit Tdata and judge whether a data type of the transition data bit Tdata is a first type or a second type.

The above-mentioned first type may be, for example, a Fix, and the second type may be, for example, a Float. In the following or the description of the drawings, the Fix may be taken as an example of the first type, and the Float may be taken as an example of the second type for description. It is required to be understood that, the first type data and the second type data may also be any other suitable data type.

If the data type of the transition data bit Tdata is the Fix, the Tdata may enter the second selector. In the second selector, whether the transition data bit Tdata is less than 0 may be judged. If the transition data bit Tdata is less than 0 (in other words, the transition data bit Tdata is negative), the complement of the transition data bit Tdata may be calculated in the first complement calculator, and the complement of the transition data bit Tdata may be taken as the intermediate data bit ABS. Calculating the complement is actually to invert other bits, other than a sign bit, and add 1. Therefore, the first complement calculator may include a first inverter and a first adder. However, if the transition data bit Tdata is greater than or equal to 0 (in other words, the transition data bit Tdata is not negative), the intermediate data bit ABS is equal to the transition data bit Tdata.

If the data type of the transition data bit Tdata is the Float, the Tdata may enter the first normalizer. In the first normalizer, the transition data bit Tdata may be normalized, and normalized data may be taken as the intermediate data bit ABS.

Normalization is an operation for Float-type numbers. There are several types of Float-type numbers in the definition of an IEEE754 standard, including a normalized number, a denormalized number, a zero, a positive infinity, a negative infinity, and non-numbers. In this operation, 1 may be added to the front of all normalized numbers, and 0 may be complemented to the back of all denormalized numbers, and actual original codes that constitute the numbers represent a result. The result has one more bit than results represented by the normalization/non-normalization in the Float type.

Further, as shown in FIG. 4a, the first computation unit C1 may include: an exponent bit calculation circuit C12 configured to calculate the intermediate exponent bit EXP according to the transition exponent bit Tshift. According to an implementation of the present disclosure, the above-mentioned intermediate exponent bit (EXP) is equal to the transition exponent bit Tshift.

Further, as shown in FIG. 4a, according to an implementation of the present disclosure, a sign bit calculation circuit C13 may be a straight connection line. The first computation unit C1 may further include: the sign bit calculation circuit C13 configured to calculate the intermediate sign bit SIGN according to the transition sign bit Tsign. It is required to be understood that since a sign does not change, the intermediate sign bit SIGN may be calculated through the straight connection line according to the transition sign bit Tsign.

Further, as shown in FIG. 4b, according to an implementation of the present disclosure, the intermediate result may further include an intermediate rounding bit STK. In order to calculate the immediate rounding bit STK, the first computation unit C1 may further include: a rounding bit calculation circuit C14.

According to an implementation of the present disclosure, the rounding bit calculation circuit C14 may be configured to calculate the intermediate rounding bit according to the intermediate data bit ABS and the intermediate sign bit SIGN.

According to another implementation of the present disclosure, the rounding bit calculation circuit C14 may be configured to calculate the intermediate rounding bit according to the intermediate data bit ABS, the intermediate exponent bit EXP, and the intermediate sign bit SIGN.

In the above two implementations of calculating the intermediate rounding bit STK, the intermediate exponent bit EXP may be used or may not be used. For example, if the intermediate rounding bit STK adopts a manner of an array (for example, all rounding contents are required to be reserved), the intermediate exponent bit EXP may not be adopted; if the intermediate rounding bit is especially required to indicate one or several bits, the intermediate exponent bit EXP may be adopted.

According to an implementation of the present disclosure, the rounding bit calculation circuit C14 may be implemented by an and-or logic. For example, rounding up and rounding down: STK=ABS; and rounding toward a positive infinity: STK[n]=|ABS[n:x1]&&˜SIGN, and the like.

As shown in FIG. 4a, through the above-mentioned converter and method, all types of data may be converted into an intermediate result with a same content. In other words, according to an implementation of the present disclosure, the intermediate result may include the intermediate sign bit SIGN, the intermediate exponent bit EXP, and the intermediate data bit ABS.

As shown in FIG. 4b, according to another implementation of the present disclosure, the intermediate result may include the intermediate sign bit SIGN, the intermediate exponent bit EXP, the intermediate data bit ABS, and the intermediate rounding bit STK.

The rounding bit calculation circuit C14 in both FIG. 4a and FIG. 4b may be placed on the second conversion stage L2; in other words, the second conversion stage L2 may receive the intermediate result including the intermediate sign bit SIGN, the intermediate exponent bit EXP, and the intermediate data bit ABS and calculate the intermediate rounding bit STK according to the intermediate result.

Further, according to another implementation of the present disclosure, the rounding bit calculation circuit may be an individual unit, where the unit may exist independently of the first conversion stage L1 and the second conversion stage L2.

Although the above makes descriptions in combination with FIG. 4a, FIG. 4b, FIG. 5a, and FIG. 5b, those skilled in the art may understand that circuits, units and other components in these figures may exist individually, or may be combined, or may be in combination with other conversion stages.

Through the second conversion stage L2, the intermediate result may be converted into types of data that are required.

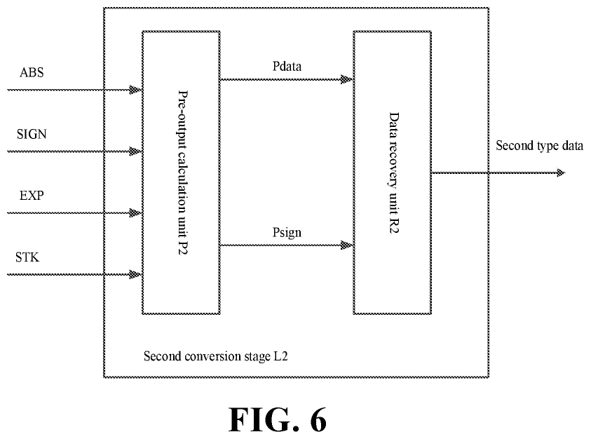

FIG. 6 shows a schematic block diagram of a second conversion stage L2 according to an implementation of the present disclosure.

As shown in FIG. 6, the second conversion stage L2 may include a pre-output calculation unit P2 and a data recovery unit R2, where the pre-output calculation unit P2 may be configured to calculate a pre-output data bit Pdata and a pre-output sign bit Psign according to the intermediate data bit ABS, the intermediate sign bit SIGN, the intermediate exponent bit EXP, and the intermediate rounding bit STK; and the data recovery unit R2 may be configured to generate the second type data according to the pre-output data bit Pdata and the pre-output sign bit Psign.

It is required to be understood that, although it is not shown that the second conversion stage L2 includes the rounding bit calculation circuit C14 in FIG. 6, the intermediate rounding bit STK in FIG. 6 may come from the first conversion stage L1 or the rounding bit calculation circuit C14 included in the L2 itself. Additionally, here, the pre-output calculation unit P2 receives four inputs, including the ABS, the Sign, the EXP, and the STK. However, it is required to be understood that as mentioned earlier, the calculation of the STK may be finished in the first conversion stage L1, or may be finished in the second conversion stage L2, or may be integrated in the pre-output calculation unit P2. Here, the four inputs are shown only for the sake of understanding and description without intending to place any limitation on the content of the present disclosure.

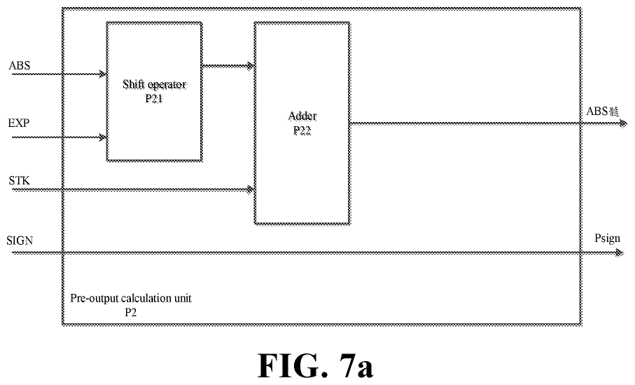

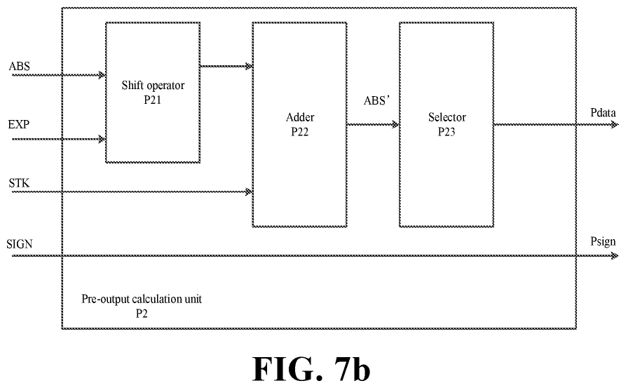

FIG. 7a shows a schematic block diagram of a pre-output calculation unit P2 according to an implementation of the present disclosure.

As shown in FIG. 7a, the pre-output calculation unit P2 may include a shift operator P21 and an adder P22, and the pre-output calculation unit P2 may be configured to generate a temporary output data bit ABS′ and a pre-output sign bit Psign. The shift operator P21 may be configured to shift the intermediate data bit ABS by the intermediate exponent bit EXP to obtain a shift result; the adder P22 may be configured to receive the shift result of the shift operator P21 and the intermediate rounding bit STK to generate the temporary output data bit ABS′; and the pre-output sign bit Psign is equal to an intermediate sign bit SIGN.

First, in the pre-output calculation unit P2, the intermediate data bit ABS received may be shifted, and the amount and direction of the shift may be determined by the intermediate exponent bit EXP. The shift result obtained may be input into a next adder.

An output of the adder is ABS′=an output result of the shift operator +STK[-EXP-1]. If the STK is out of range, the STK takes 0. It is required to be explained that the STK is an array, for example, a 32-bit array STK[31:0]. Here, a STK[0] is an element of the lowest bit, and a STK[31] is an element of the highest bit. When -EXP-1 is calculated, if the -EXP- is in a range of 0-31, a corresponding value may be taken, and if the -EXP- is less than 0, the -EXP- takes 0, and if the -EXP- is greater than 0, special processing may be performed (for example, according to the type of the STK, the -EXP- may take 0 or 31).

In a specific case, for example, if the ABS′ does not overflow, the ABS′ may be directly taken as an output of the pre-output calculation unit P2.

FIG. 7b shows a schematic block diagram of a pre-output calculation unit P2 according to another implementation of the present disclosure.

As shown in FIG. 7b, the pre-output calculation unit P2 may further include a selector P23. In the selector P23, whether the generated ABS′ overflows may be judged. If the generated ABS′ overflows, saturation processing may be performed on the ABS′, and if the generated ABS′ does not overflow, Pdata=ABS′.

The saturation processing is processing for a special case that occurs in all kinds of computation units. In the process of computation including the computation of conversion numbers, there appears a case that a result obtained from the input data may be different from a value range of the output data: if an absolute value of a result that should be obtained is greater than an upper limit of an absolute value of a representation range of the output data, there appears an overflow; if the absolute value of the result that should be obtained is less than a lower limit of the absolute value of the representation range of the output data, there appears an underflow. There are several processing methods for overflow situations: taking saturation values, truncating high bits, or taking infinity or special values. Any method may be adopted by the present disclosure for saturation processing.

Additionally, the SIGN may be output as the Psign through the straight connection line; in other words, the sign does not change.

Additionally, a pre-output exponent bit Pshift is not shown in both FIG. 7a and FIG. 7b. If all data shifts are completed, Pshift=0.

For the output data in both FIG. 7a and FIG. 7b, in some specific cases (for example, both the input and the output are the Fix and signs thereof are positive), for example, the temporary output data bit ABS′, the pre-output data bit Pdata and the pre-output sign bit Psign may directly become second output data without further processing.

FIG. 7a and FIG. 7b show another implementation of the pre-output calculation unit P2 of the present disclosure. In both FIG. 7a and FIG. 7b, both Pdata and Psign that are output may be output externally for further processing.

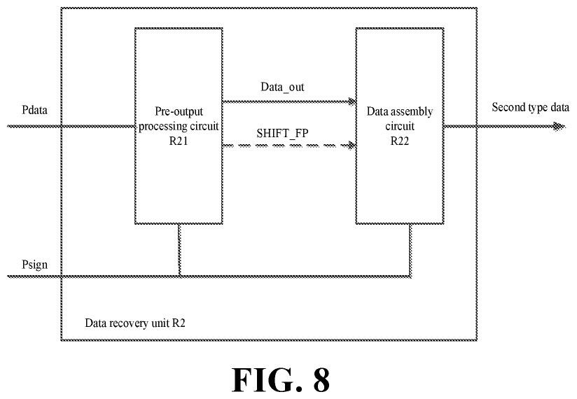

FIG. 8 shows a schematic structural diagram of a data recovery unit R2 according to an implementation of the present disclosure.

As shown in FIG. 8, the data recovery unit R2 may be configured to obtain second output data according to the pre-output data bit Pdata and the pre-output sign bit Psign.

As shown in FIG. 8, the data recovery unit R2 may include a pre-output processing circuit R21, and in some embodiments, the data recovery unit R2 may further include a data assembly circuit R22. A data assembly may be an inverse operation of the data concatenation described above; in other words, the data assembly may recover concatenated data to second type data required. Those skilled in the art may determine whether it is required to add this assembly circuit according to actual data types. For example, for data that is not concatenated, the data assembly circuit R22 may not be required, and therefore, the data assembly circuit R22 may be preferred but not necessarily required.

For example, if an input is a 32-bit Float-type number, and an output is a 32-bit Fix-type number, at this time, there is no concatenation or splitting when the number is input, and therefore, in terms of length, the data assembly circuit R22 may not be required.

As shown in FIG. 8, the pre-output processing circuit R21 in the data recovery unit R2 may receive the temporary output data bit ABS′ and the pre-output sign bit Psign in FIG. 7a, or receive the pre-output data bit Pdata and the pre-output sign bit Psign in FIG. 7b, so as to obtain an output data bit representation Data_out.

For data with a specific data type, for example, non-negative Fix-type data, the output data bit representation is equal to the pre-output data Pdata, and special deformations or processing may not be required.

Considering that there exist other data types such as Float, the pre-output processing circuit R21 of the present disclosure may be further configured to generate a floating-point number decimal point bit number representation SHIFT_FP.

Further, as shown in FIG. 8, the data assembly circuit R22 may obtain final second type data according to the output data bit representation Data_out, the floating-point number decimal point bit number representation SHIFT_FP, and the pre-output sign bit Psign. It is required to be understood that, in FIG. 8, the floating-point number decimal point bit number representation SHIFT_FP is shown by a dotted line, which shows that the SHIFT_FP, in a specific case, may not exist, and in this case, the data assembly circuit R22 may be configured to obtain the second type data according to the output data bit representation Data_out and the pre-output sign bit Psign.

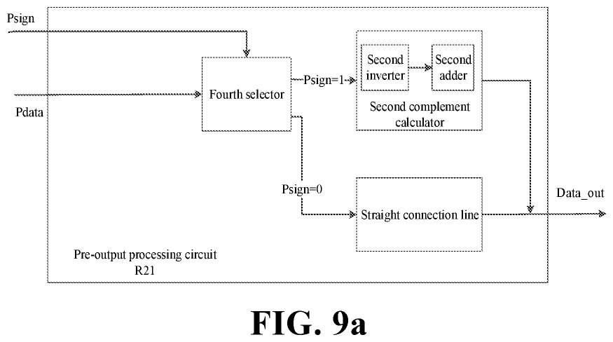

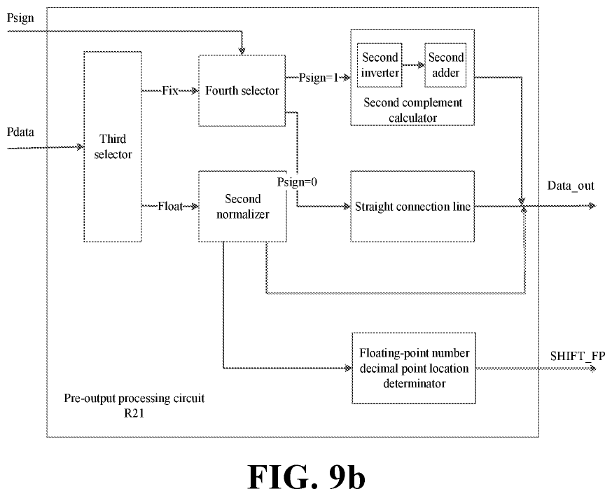

FIG. 9a shows a schematic block diagram of a pre-output processing circuit R21 according to an implementation of the present disclosure.

As shown in FIG. 9a, the pre-output processing circuit R21 of the present disclosure may include: a fourth selector and a second complement calculator.

In FIG. 9a, in the fourth selector, the Pdata and the pre-output sign bit Psign may be received. Whether the Psign is a positive number or a negative number may be judged; in other words, whether the Psign is equal to 1 or 0 may be judged.

If Psign=1, the Pdata may enter the second complement calculator, where the second complement calculator may include a second inverter and a second adder, where the second inverter may invert all bits, other than the sign bit, and then the second adder may add 1. Next, the second complement calculator outputs a result as the output data bit representation Data_out.

If Psign=0, the Pdata may be directly output as the output data bit representation Data_out.

Considering that the data has a plurality of types, the pre-output data bit Pdata may be judged in advance to determine subsequent processing.

FIG. 9b shows a schematic block diagram of a pre-output processing circuit R21 according to another implementation of the present disclosure.

As shown in FIG. 9b, the pre-output processing circuit R21 may further include: a third selector, a second normalizer, and a floating-point number decimal point location determinator.

The third selector may receive the pre-output data bit Pdata and judge whether a data type of the pre-output data bit Pdata is a Fix or a Float. If the data type of the pre-output data bit Pdata is the Fix, the pre-output data bit Pdata may be sent to the fourth selector, and if the data type of the pre-output data bit Pdata is the Float, the pre-output data bit Pdata may be sent to the second normalizer.

The second normalizer may normalize the pre-output data bit Pdata and output the normalized pre-output data bit as the output data bit representation Data_out.

In the definition of normalized numbers, it is through a simple size comparison to distinguish normalized numbers and denormalized numbers. If an absolute value is greater than a representable maximum value of the absolute value (positive and negative saturation values), there is no representation, and there appears an overflow and saturation processing may be performed; if the absolute value is less than the saturation value and greater than a normalization threshold, a normalization operation may be performed; if the absolute value is less than the normalization threshold and greater than a representable minimum value of the absolute value, a non-normalization operation may be performed; if the absolute value is less than the representable minimum value of the absolute value, there appears an underflow and the saturation processing may be performed (such as taking 0, taking the representable minimum value of the absolute value, or taking a special value). In the second conversion stage L2, normalization is to delete 1 in the first place, and non-normalization is to shift 1 bit to the right, which is an inverse operation of the previous normalization operation in the first conversion stage L1.

The floating-point number decimal point location determinator may determine the floating-point number decimal point bit number representation SHIFT_FP according to an output of the second normalizer.

It is required to be noted that data of various phrases above may keep consistent in terms of the number of bits in each phrase. For example, if the first type data is concatenated (for example, two pieces of 16-bit data are concatenated to form one piece of 32-bit data), the transition data bit Tdata is one piece of data that is concatenated by two pieces of data. Similarly, the intermediate result (for example, the Sign, the ABS, the EXP, and the STK), the pre-output data (for example, the pre-output data bit Pdata and the pre-output sign bit Psign), the output data bit representation Data_out, and the floating-point number decimal point bit number representation SHIFT_FP may be data that is concatenated by two pieces of data. The form of concatenation may be set according to user requirements.

For the data assembly circuit R22, there may exist a plurality of cases.

For example, for a 32-bit converter, if the input is a 16-bit Fix-type number, and the output is the 32-bit Fix-type number, converting a 16-bit number that is input to a 32-bit number may be operated by simply adding 0 to the high bits, and then a final output may directly be the 32-bit number without any data assembly.

For another example, for the 32-bit converter, if the input is the 32-bit Fix-type number, and the output is the 16-bit Fix-type number, the input may be converted normally in the first conversion stage, and based on the converted data, a final 16-bit Fix-type number may be obtained by truncating 16 bits of the high bits.

It may be shown that the above-mentioned data assembly circuit R22, in some cases, may not function, and therefore, the data assembly circuit R22 may not be necessarily required in the present disclosure.

Additionally, since the output data bit representation Data_out and the floating-point number decimal point bit number representation SHIFT_FP that are output by the pre-output processing circuit R21 may be data that is concatenated by a plurality of pieces of data, therefore, the data assembly circuit R22 may be adopted to convert or assemble the data to a data form that is required finally. For example, the concatenated data may be split, or parts of the data (for example, a significant data part and a sign part) may be assembled.

For example, the data of Data_out may be {0000 0000 0000 0000 0101 0011 0001 1010}, and the sign bit of the data may be {0001}, and at this time, a number that is required to be output is a Fix8, and the data assembly circuit R22 may extract two pieces of final second type data from the above data, which are {0101 0011} and {0001 1010} respectively, and signs of the data are 0 and 1 respectively. Therefore, the data assembly circuit may extract final data from the Data_out.

The first conversion stage L1 of the present disclosure may further receive constraint information, where the constraint information may be used to indicate whether the converter supports a specific standard and/or supports a compiler optimization. The specific standard may be any known or unknown standard that is suitable for the present disclosure, for example, IEEE754; and the compiler optimization may be, for example, a support of compiler behaviors such as −o0 and −o1.

It is required to be understood that the above description is only for specific embodiments, and these embodiments are only for the sake of description and do not form any limitation on the protection scope of the present disclosure. The data type of the first type data, the data type of the second type data, and the content of the constraint information may be expanded to any extent, and any existing or newly-developed data types in the future may be implemented according to the technical solutions of the present disclosure.

In the above, when intermediate data passes through the second conversion stage L2, there may exist a plurality of states, such as an output of the adder ABS′ in FIG. 7a, an output of the selector Pdata in FIG. 7b, and an output of the pre-output processing circuit Data_out in FIG. 8, FIG. 9a and FIG. 9b, and the like. These pieces of data (optionally, these pieces of data may be added with other pieces of auxiliary data) may be equal to the second type data. For example, the ABS′ may be equal to the second type data, and ABS′+Pdata may be equal to the second type data; similarly, the Pdata may be equal to the second type data, and Pdata+Psign may be equal to the second type data. The difference between the Pdata and the Pdata plus Psign lies in the sign bit; for another example, the Data_out may be equal to the second type data, and Data_out+SHIFT_FP may also be equal to the second type data. It is required to be understood that although these pieces of data of different phrases may be represented by different signs, for some pieces of data, the data may be the same or different; in other words, the “second type data” in the present disclosure may be any of the above data, but the only difference is the way that the data is represented in each figure. For example, if an input number is a Fix16 that is a positive number and is expanded to a 32-bit number, and an output number is a Fix32, the Pdata may be distributed as the Data_out to be directly output after passing through the fourth selector (as shown in FIG. 9a). Since the data of the Data_out itself is compatible with the form of the Fix32, further processing may not be required, and the data may be directly output as the second type data.

The following will describe the above-mentioned various units, circuits and components in combination with detailed embodiments.

### Embodiment 1

Embodiment 1 shows an embodiment of converting a Fix8 into a Float16.

Assuming that input numbers are 81 and 82 with the data type of the Fix8, and the data type of the output is the Float16, a hexadecimal number DATA that is concatenated by the two numbers is DATA=32′h 00008182 (0000 0000 0000 0000 1000 0001 1000 0010), with a 9-bit exponent bit Shift, for example, −1(1 1111 1111) and a rounding method of rounding up and rounding down. 32′ described above represents 32 bits, and h represents the hexadecimal.

As shown in FIG. 1 to FIG. 3, after concatenation, a 32-bit number may be formed; in other words, an output that passes through the first data parsing unit P1 is as follows:

the transition data bit Tdata is 32′h ff81 ff82.

A concatenated shift, which means that the transition exponent bit Tshift is −1 (1 1111 1111), is equal to an original input.

The Sign extracted is 0011, where only two numbers are significant, (11, which are signs of 81 and 82 respectively), and invalid positions are 0; if the significant numbers are two negative numbers, the value is 1. In other words, the transition sign bit Tsign is 0011.

It is required to be understood that the above description is based on the concatenated data as an object, and if taking a piece of single data as the object (for example, 81) and using actual values for description (for example, data before the concatenation), the transition data bit may be 81, and the transition exponent bit may be −1, and the transition sign bit may be 1.

As shown in FIG. 3, after calculation, especially after passing through the first computation unit C1, the following may be obtained:

ABS=32′h 007f 007e, and the data type of the input is the Fix, and the complement may be taken through the selector.

EXP=−1 (1 1111 1111), which is equal to the transition exponent bit.

SIGN=0011 (which is directly equal).

STK=32′h 007f 007e (when rounding up and rounding down, STK=ABS).

Next, the intermediate result including the ABS, the EXP, the SIGN, and the STK may be input to the second conversion stage L2 (as shown in FIG. 6 to FIG. 9b):

through the shift operator P21, since EXP=−1, the EXP may be shifted to the right by one bit to obtain the shift result=32′h 003f 003f;

through the adder P22, if a number that is used to be summed is STK[−EXP −1]=STK[0] (in other words, if the number that is used to be summed is STK[−EXP −1], STK[0]), and if two numbers correspond to STK[16] =1 and STK[0] =0: the high 16 bits that are output by the adder are [31:16] =16′h 003f+STK[16]=16′h 0040, and the low 16 bits that are output by the adder are [15:0]=16′h 003f+STK[0]=16′h 003f. Therefore, the output of the adder=32′h 0040 003f.

Through the selector P23, obviously, the output of the adder P22 is relatively small, and there is no overflow, which does not include exceptions. Additionally, Pdata=the output of the adder=32′h 0040 003f=0000 0000 0100 0000 0000 0000 0011 1111.

Next, the data may enter the pre-output processing circuit R21, as shown in FIG. 8.

If the type of the output is a Float16, the Pdata may be normalized, and DATA_out=32′h 0000 001f.

SHIFT_FP ={6-15, 5-15}={-9, -10}={10111, 10110}.

Next, the data may enter the data assembly circuit R22, as shown in FIG. 8.

The SIGN, the SHIFT_FP, and the DATA_out may be assembled as two pieces of Float16-type data.

The second type data={1, 10111, 0000000000, 1, 10110, 0000011111}=32′h dc00 d81f.

### Embodiment 2

Embodiment 2 shows an example that a Float16 is converted into a Fix8, with SHIFT=−3.

Assuming that DATA =32′h c001 4401(1100 0000 0000 0001 0100 0100 0000 0001),

SHIFT=−3, and

the rounding method is rounding toward a positive infinity,

as shown in FIG. 1-FIG. 3,

Tdata=32′h 0401 0401 (0000 0100 0000 0001 0000 0100 0000 0001) (where there are only two significant numbers, where each of them has 11 bits and other numbers of bits are expanded in the sign bit, and since a fp itself is represented by an original code, the sign bit may be filled with 0);

Tshifit={16, 17} (10000 10001), and the type of the input is the Float, and the numbers of bits in the middle are taken to be directly equal; and

Tsign=0010 (where only two numbers are significant and invalid positions are 0, and since two significant numbers include one negative number and one positive number, the two significant numbers may be set as 10).

As shown in FIG. 3, after calculation, especially after the first computation unit C1, the following may be obtained:

ABS=32′h 0401 0401, and the data type of the input is the Float, and ABS=Tdata may be output directly in the form of the original code;

EXP ={16-15-(3), 17-15-(3)} ={-2, -1} (where the type of the input is the Float, and a shift code -15 may be taken first and then be made a difference with an output shift) ={11110 11111};

SIGN=0010 (which is directly equal);

STK=32′h 0000 ffff. When rounding toward a positive infinity, in this example, if data representation bit numbers are ABS[31:16] and ABS[15:0], STK[n]=ABS[n:x1] && SIGN, where x2>=n>=x1. For the high 16 bits of the 32-bit number, x2=31, and x1=16; for the low 16 bits of the 32-bit number, x2=15, and x1=0.

Next, the intermediate result including the ABS, the EXP, the SIGN, and the STK may be input to the second conversion stage L2 (as shown in FIG. 6 to FIG. 9b):

through the shift operator P21, since EXP={-2, -1}, the EXP may be shifted to the right by 2 bits and 1 bit respectively to obtain the shift result=32′h 0008 0010;

through the adder P22, if the number that is used to be summed is STK[-EXP -1] =STK[2], STK[1], and if the two numbers correspond to STK[18]=0, STK[1]=1: the high 16 bits that are output by the adder are [31:16]=16′h 0008+STK[18]=16′h 0008, and the low 16 bits that are output by the adder are [15:0]=16′h 0010+STK[1]=16′h 0011. Therefore, the output of the adder=32′h 0008 0011.

Through the selector P23, obviously, the output of the adder is relatively small, and there is no overflow, which does not include exceptions. Additionally, Pdata=the output of the adder=32′h 0008 0011 =0000 0000 0000 1000 0000 0000 0001 0001.

Next, the data may enter the pre-output processing circuit R21, as shown in FIG. 8.

If the type of the output is the Fix, the Pdata may be represented by taking the complement, and DATA_out=32′h fff8 0011.

Next, the data may enter the data assembly circuit R22, as shown in FIG. 8.

The DATA_out obtained may be converted into two pieces of Fix8-type data and be placed on the low bit, and the invalid numbers of the high 16 bits may be set as zeros.

The second type data=32′h 0000 f811 may be obtained.

Based on the aforementioned devices, the present disclosure provides a method, as shown in FIG. 2, and other operations and steps of the method of the present disclosure may not be shown in the drawings for the sake of simplicity. The operations of the method of the present disclosure may be based on specific devices, units and circuits that are recorded in the present disclosure, or based on other software, hardware, and firmware, which is not limited to the aforementioned detailed structure.

An aspect of the present disclosure provides an electronic device, including: one or a plurality of processors; and a memory, where the memory stores computer-executable instructions, and when the computer-executable instructions are executed by the one or the plurality of processors, the electronic device performs the above-mentioned method.

An aspect of the present disclosure provides a computer-readable storage medium, including computer-executable instructions, where, when the computer-executable instructions are executed by one or a plurality of processors, the above-mentioned method is performed.

In traditional actual calculations, there are few conversion types and few constraints in the data type conversion. Most of them may be completed in less clock cycles with simple software behaviors and instructions. More importantly, frequency of data type conversion instructions is very low.

However, in artificial intelligence chips, since there are different requirements for precision, a requirement for the data type conversion is likely to occur in the calculation of each step, and once the requirement occurs, not a small number of calculations are required, but very intensive large-scale calculations are required, and the data organization of the calculations is very regular. If a traditional data type conversion method is used, the intensive large-scale calculations may produce a large memory access delay. Since the frequency of data type conversion instructions is relatively high, this bottleneck may affect overall calculation performance of a processor core.

Additionally, a simple stacking of conversion number instructions may cause a large amount of logic redundancy in a conversion number unit, resulting in an excessively large local area and a dense wiring, which may affect the local performance of a processor. The following will explain the problem of logic redundancy with an example: in a data type conversion process of converting a Fix4 to a fp16, the Fix4 may be required to be converted into an absolute value form, and the rounding bit may be calculated based on the absolute value form, and in a final phrase of the data conversion, the same numerical data may be represented by fixed points and be converted into data that is represented by floating-point number 10-bit mantissas in a normal or a denormal form, and the concatenation of the output number may be completed finally by the sign bit, the exponent, and the mantissa. Actually, in the process of converting the Fix4 to the fp16, an exact same first half of the logic is required: the Fix4 may be converted into the absolute value form, and the rounding bit may be calculated based on the absolute value form; when converting the Fix8 to the fp16, an exact same second half of the logic is required: the same numerical data may be represented by the fixed points and be converted into the data that is represented by the floating-point number 10-bit mantissas in the normal or the denormal form, and the concatenation of the output number may be completed finally by the sign bit, the exponent, and the mantissa. If an instruction set is simply expanded, there may be a lot of hardware operations with repeated logic and repeated calculations (if complier behavior software is used to control the calculation of logic of this part, this part of redundant calculation may not disappear and the repeated calculations may be performed in software implementations), performance of the processor may be affected.

The main purpose of this structure design of the intermediate result of the present disclosure is to reduce repeated calculation logic and compared with the software implementations, reduce memory access delay and overheads, and simultaneously have better scalability and portability. For example, as long as an intermediate result that may represent any data type is obtained, flexible processing may be performed on the intermediate result, and it is not necessarily required to employ specific circuits and structures described in the present disclosure. The content of the present disclosure may be easily ported to other processing units, such as a traditional central processing unit (CPU) and a traditional graphics processing unit (GPU).

In the aforementioned embodiments of the present disclosure, the description of each embodiment has its own emphasis. A part that is not described in detail in one embodiment may be described with reference to related descriptions in other embodiments. Each technical feature of the embodiments above may be randomly combined. For the sake of conciseness, not all possible combinations of technical features of the embodiments above are described. Yet, provided that there is no contradiction, combinations of these technical features may fall within the scope of the description of the present specification.

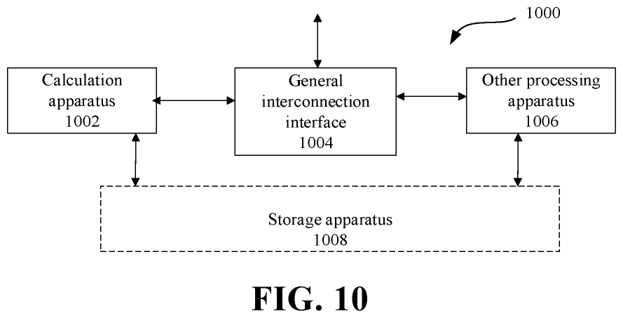

The present disclosure also provides a combined processing apparatus 1000, including the above-mentioned calculation apparatus 1002, a general interconnection interface 1004, and other processing apparatus 1006. The calculation apparatus of the present disclosure interacts with other processing apparatus to jointly complete operations specified by users. FIG. 10 is a schematic diagram of a combined processing apparatus.

Other processing apparatus may include at least one or more than one of general-purpose/special-purpose processors such as a central processing unit (CPU), a graphics processing unit (GPU), a neural network processor, and the like. A count of processors included in other processing apparatus is not limited herein. Other processing apparatus may serve as an interface that connects a machine learning computation apparatus to external data and control including data moving, and may perform basic controls such as starting and stopping the machine learning computation apparatus. Additionally, other processing apparatus may also cooperate with the machine learning computation apparatus to complete computation tasks.

A general interconnection interface may be used to transfer data and control instructions between the calculation apparatus (including, for example, the machine learning computation apparatus) and other processing apparatus. The calculation apparatus may obtain input data required from other processing apparatus and write the data in an on-chip storage apparatus of the calculation apparatus. The calculation apparatus may also obtain the control instructions from other processing apparatus and write the control instructions in an on-chip control caching unit of the calculation apparatus. Additionally, the calculation apparatus may further read data stored in a storage unit of the calculation apparatus and transfer the data to other processing apparatus.

Optionally, this structure may further include a storage apparatus 1008. The storage apparatus may be connected to the calculation apparatus and other processing apparatus, respectively. The storage apparatus may be configured to store data of the calculation apparatus and other processing apparatus. The storage apparatus may be especially suitable for storing data that may not be completely stored in an internal storage of the calculation apparatus or other processing apparatus.

The combined processing apparatus may be used as a system on chip (SOC) of a device including a mobile phone, a robot, a drone, a video surveillance device, and the like, which may effectively reduce a core area of a control part, increase processing speed, and reduce overall power consumption. In this case, the general interconnection interface of the combined processing apparatus may be connected to some components of the device. The some components include, for example, a webcam, a monitor, a mouse, a keyboard, a network card, and a WIFI interface.

In some embodiments, the present disclosure also provides a chip, including the above-mentioned calculation apparatus or the combined processing apparatus.

In some embodiments, the present disclosure also provides a chip package structure, including the above-mentioned chip.

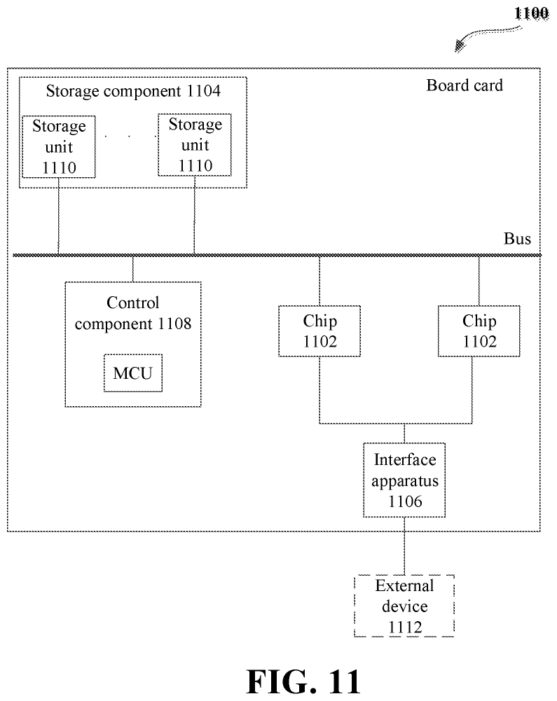

In some embodiments, the present disclosure also provides a board card, including the above-mentioned chip package structure. Referring to FIG. 11, FIG. 11 shows an exemplary board card. The above-mentioned board card, apart from the above-mentioned chip 1102, may further include other supporting components, where the supporting components include but are not limited to: a storage component 1104, an interface apparatus 1106, and a control component 1108.

The storage component may be connected to a chip in a chip package structure through a bus, and the storage component may be used for storing data. The storage component may include a plurality of groups of storage units 1110. Each group of the storage units may be connected to the chip through the bus. It may be understood that each group of the storage units may be a double data rate (DDR) synchronous dynamic random access memory (SDRAM).

The DDR may double the speed of the SDRAM without increasing clock frequency. The DDR may allow data to be read on rising and falling edges of a clock pulse. The speed of the DDR is twice that of a standard SDRAM. In an embodiment, a storage apparatus may include 4 groups of storage units. Each group of the storage units may include a plurality of DDR4 particles (chips). In an example, four 72-bit DDR4 controllers may be arranged inside the chip, where 64 bits of each 72-bit DDR4 controller are used for data transfer and 8 bits are used for an error checking and correcting (ECC) parity. In an embodiment, each group of the storage units may include a plurality of DDR SDRAMs arranged in parallel. The DDR may transfer data twice in one clock cycle. A controller for controlling the DDR may be arranged in the chip, and the controller may be used to control data transfer and data storage of each storage unit.

The interface apparatus may be electrically connected to the chip in the chip package structure. The interface apparatus may be used to implement data transfer between the chip and an external device 1112 (such as a server or a computer). For example, in an embodiment, the interface apparatus may be a standard peripheral component interconnect express (PCIe) interface. For example, to-be-processed data may be transferred from the server to the chip through the standard PCIe interface to realize data transfer. In another embodiment, the interface apparatus may also be other interfaces. Specific representations of other interfaces are not limited in the present disclosure, as long as an interface unit may realize a switching function. Additionally, a calculation result of the chip is still sent back to the external device (such as the server) by the interface apparatus.

The control component may be electrically connected to the chip. The control component may be used to monitor a state of the chip. Specifically, the chip and the control component may be electrically connected through a serial peripheral interface (SPI). The control component may include a micro controller unit (MCU). If the chip may include a plurality of processing chips, a plurality of processing cores, or a plurality of processing circuits, the chip may be capable of driving a plurality of loads. Therefore, the chip may be in different working states, such as a multi-load state and a light-load state. Through the control apparatus, regulation and controls of working states of the plurality of processing chips, the plurality of processing cores, and/or the plurality of processing circuits in the chip may be realized.

In some embodiments, the present disclosure also provides an electronic device or apparatus, including the above-mentioned board card.

The electronic device or apparatus may include a data processing apparatus, a robot, a computer, a printer, a scanner, a tablet, a smart terminal, a mobile phone, a traffic recorder, a navigator, a sensor, a webcam, a server, a cloud-based server, a camera, a video camera, a projector, a watch, a headphone, a mobile storage, a wearable device, a vehicle, a household appliance, and/or a medical device.

The vehicle may include an airplane, a ship, and/or a car. The household appliance may include a television, an air conditioner, a microwave oven, a refrigerator, an electric rice cooker, a humidifier, a washing machine, an electric lamp, a gas cooker, and a range hood. The medical device may include a nuclear magnetic resonance spectrometer, a B-ultrasonic scanner, and/or an electrocardiograph.

The foregoing may be better understood according to the following articles.

Article A1. A converter for data type conversion, including: a first conversion stage (L1) configured to receive first type data and descriptive information about the first type data and second type data and according to the descriptive information, convert the first type data into an intermediate result; and a second conversion stage (L2) configured to convert the intermediate result into the second type data.

Article A2. The converter of article Al, where the first conversion stage (L1) includes a first data parsing unit (P1) and a first computation unit (C1), where the first data parsing unit (P1) is configured to generate a transition sign bit (Tsign), a transition data bit (Tdata), and a transition exponent bit (Tshift) according to the first type data and the descriptive information; and the first computation unit (C1) is configured to generate the intermediate result according to the transition sign bit (Tsign), the transition data bit (Tdata), and the transition exponent bit (Tshift).

Article A3. The converter of article Al or article A2, where the intermediate result includes an intermediate data bit (ABS), an intermediate sign bit (SIGN), and an intermediate exponent bit (EXP), and the first computation unit (C1) includes: an absolute value calculation circuit (C11) configured to calculate the intermediate data bit (ABS) according to the transition data bit (Tdata); an exponent bit calculation circuit (C12) configured to calculate the intermediate exponent bit (EXP) according to the transition exponent bit (Tshift); and a sign bit calculation circuit (C13) configured to calculate the intermediate sign bit (SIGN) according to the transition sign bit (Tsign).

Article A4. The converter of any one of articles A1-A3, where the intermediate result further includes an intermediate rounding bit (STK), and the first computation unit (C1) further includes: a rounding bit calculation circuit (C14) configured to calculate the intermediate rounding bit (STK) according to the intermediate data bit (ABS), the intermediate exponent bit (EXP), and the intermediate sign bit (SIGN).

Article A5. The converter of article A3, where the intermediate result further includes an intermediate rounding bit (STK), and the first computation unit (C1) further includes: a rounding bit calculation circuit (C14) configured to calculate the intermediate rounding bit (STK) according to the intermediate data bit (ABS) and the intermediate sign bit (SIGN).

Article A6. The converter of any one of articles A1-A5, where the absolute value calculation circuit (C11) includes:

a second selector configured to judge whether the transition data bit (Tdata) is less than 0; and a first complement calculator configured to calculate a complement of the transition data bit and take the complement of the transition data bit as the intermediate data bit (ABS) if the transition data bit (Tdata) is less than 0, otherwise, take the transition data bit (Tdata) as the intermediate data bit (ABS).

Article A7. The converter of any one of articles A1-A6, where the absolute value calculation circuit (C11) further includes a first selector and a first normalizer, where the first selector is configured to judge whether a data type of the transition data bit (Tdata) is a first type or a second type; if the data type of the transition data bit (Tdata) is the first type, the first selector selects the second selector for processing; if the data type of the transition data bit (Tdata) is the second type, the first selector selects the first normalizer for processing; and the first normalizer is configured to normalize the transition data bit (Tdata) and take the normalized transition data bit as the intermediate data bit (ABS) if the data type of the transition data bit (Tdata) is the second type.

Article A8. The converter of any one of articles A1-A7, where an output of the exponent bit calculation circuit (C12), which is the intermediate exponent bit (EXP), is equal to the transition exponent bit (Tshift).

Article A9. The converter of any one of articles A1-A8, where the sign bit calculation circuit (C13) is a straight connection line.

Article A10. The converter of any one of articles A1-A9, where the first conversion stage (L1) is further configured to determine the number of first type data received and concatenate the first type data to form first concatenation data, and the first conversion stage (L1) converts the first concatenation data into the intermediate result according to the descriptive information.

Article A11. The converter of any one of articles A1-A10, where the number of first type data received is determined by: by a preset first fixed value, or by the number of processing bits of the converter, dividing the number of bits of data with the highest number of bits in the first type data and the second type data.

Article Al2. The converter of any one of articles A1-A11, where the first conversion stage (L1) is further configured to determine the number of to-be-split first type data received and split the first type data into split data with the same number, and the first conversion stage (L1) converts the split data into the intermediate result according to the descriptive information.

Article A13. The converter of any one of articles A1-Al2, where the number of to-be-split first type data received is determined by: by a preset second fixed value, or by the number of bits of data with the highest number of bits in the first type data and the second type data, dividing the number of processing bits of the converter.

Article A14. The converter of any one of articles A1-A13, where the descriptive information includes: first descriptive information configured to describe a data type of the first type data and a first exponent bit of the first type data; and second descriptive information configured to describe a data type of the second type data and a second exponent bit of the second type data, where the transition exponent bit (Tshift) is equal to a difference between the first exponent bit and the second exponent bit.

Article A15. The converter of any one of articles A1-A14, where the descriptive information includes: the first data type of the first type data; the second data type of the second type data; and a difference exponent bit configured to indicate a difference between the first exponent bit of the first type data and the second exponent bit of the second type data, where the transition exponent bit (Tshift) is equal to the difference exponent bit.

Article A16. The converter of any one of articles A1-A15, where the descriptive information further includes a rounding type, where the rounding type includes at least one of the followings: a TO_ZERO, an OFF_ZERO, an UP, a DOWN, a ROUNDING_OFF_ZERO, a ROUNDING_TO_EVEN, and a random rounding.

Article A17. The converter of any one of article A1-A16, where the second conversion stage (L2) includes the rounding bit calculation circuit (C14) configured to calculate the intermediate rounding bit (STK) according to the intermediate data bit (ABS) and the intermediate sign bit (SIGN).

Article A18. The converter of any one of articles A1-A17, where the second conversion stage (L2) further includes the rounding bit calculation circuit (C14) configured to calculate the intermediate rounding bit (STK) according to the intermediate data bit (ABS), the intermediate exponent bit (EXP), and the intermediate sign bit (SIGN).

Article A19. The converter of any one of articles A1-A18, where the second conversion stage (L2) is further configured to generate the second type data according to the intermediate data bit (ABS), the intermediate sign bit (SIGN), the intermediate exponent bit (EXP), and the intermediate rounding bit (STK).

Article A20. The converter of any one of articles A1-A19, where the rounding bit calculation circuit (C14) is implemented by an and-or logic.

Article A21. The converter of any one of articles A1-A20, where the second conversion stage (L2) includes: a pre-output calculation unit (P2) and a data recovery unit (R2), where the pre-output calculation unit (P2) is configured to calculate a pre-output data bit (Pdata) and a pre-output sign bit (Psign) according to the intermediate data bit (ABS), the intermediate sign bit (SIGN), the intermediate exponent bit (EXP), and the intermediate rounding bit (STK); and the data recovery unit (R2) is configured to generate the second type data according to the pre-output data bit (Pdata) and the pre-output sign bit (Psign).

Article A22. The converter of any one of articles A1-A21, where the pre-output calculation unit (P2) includes a shift operator (P21) and an adder (P22), and the pre-output calculation unit (P2) is configured to generate a temporary output data bit (ABS′) and the pre-output sign bit (Psign), where the shift operator (P21) is configured to shift the intermediate data bit (ABS) by the intermediate exponent bit (EXP) to obtain a shift result; the adder (P22) is configured to generate the temporary output data bit (ABS′) according to the shift result and the intermediate rounding bit (STK); and the pre-output sign bit (Psign) is equal to the intermediate sign bit.

Article A23. The converter of any one of articles A1-A22, where the pre-output calculation unit (P2) further includes a selector (P23), where the selector (P23) is configured to detect whether the temporary output data bit (ABS′) is greater than a saturation value, where, if the temporary output data bit (ABS′) is greater than the saturation value, saturation processing is performed on the temporary output data bit (ABS′) to obtain the pre-output data bit (Pdata); and if the temporary output data bit (ABS′) is not greater than the saturation value, the temporary output data bit (ABS′) is output as the pre-output data bit (Pdata).

Article A24. The converter of any one of articles A1-A23, where the data recovery unit (R2) includes a pre-output processing circuit (R21) and a data assembly circuit (R22), where the pre-output processing circuit (R21) is configured to receive the pre-output data bit (Pdata) and the pre-output sign bit (Psign) to generate an output data bit representation (Data_out); and the data assembly circuit (R22) is configured to generate the second type data according to the output data bit representation (Data_out) and the pre-output sign bit (Psign).

Article A25. The converter of any one of articles A1-A24, where the pre-output processing circuit (R21) is further configured to generate a floating-point number decimal point bit number representation (SHIFT_FP), and the data assembly circuit (R22) is configured to generate the second type data according to the output data bit representation (Data_out), the floating-point number decimal point bit number representation (SHIFT_FP), and the pre-output sign bit (Psign).

Article A26. The converter of any one of articles A1-A25, where the pre-output processing circuit (R21) includes a fourth selector and a second complement calculator, where the fourth selector is configured to receive the pre-output data bit (Pdata) and the pre-output sign bit (Psign); if the pre-output sign bit (Psign) is a negative number, the fourth selector outputs the pre-output data bit to the second complement calculator; if the pre-output sign bit (Psign) is not the negative number, the fourth selector outputs the pre-output data bit as the output data bit representation (Data_out); and the second complement calculator is configured to calculate a complement for the the pre-output data bit (Pdata).

Article A27. The converter of any one of articles A1-A25, where the pre-output processing circuit (R21) further includes a third selector, a second normalizer, and a floating-point number decimal point location determinator, where the third selector is configured to receive the pre-output data bit (Pdata) and judge whether a data type of the pre-output data bit (Pdata) is the first type or the second type; if the data type of the pre-output data bit (Pdata) is the first type, the third selector sends the pre-output data bit (Pdata) to the fourth selector; if the data type of the pre-output data bit (Pdata) is the second type, the third selector sends the pre-output data bit (Pdata) to the second normalizer; the second normalizer is configured to normalize the pre-output data bit (Pdata) and output the normalized pre-output data bit as the output data bit representation (Data_out); and the floating-point number decimal point location determinator is configured to determine the floating-point number decimal point bit number representation (SHIFT_FP) according to an output of the second normalizer.

Article A28. The converter of any one of articles A1-A27, where the first conversion stage (L1) is further configured to receive constraint information, where the constraint information is used to indicate whether a specific standard is supported, and/or a compiling optimization is supported.

Article A29. The converter of any one of articles A1-A28, where the data type of the first type data and the data type of the second type data are scalable.

Article A30. A chip, including the converter of any one of articles A1-A29.

Article A31. A calculation apparatus, including the converter of any one of articles A1-A29 or the chip of article 30.

Article A32. A method for data type conversion, including: receiving first type data and descriptive information about the first type data and second type data and according to the descriptive information, converting the first type data into an intermediate result; and converting the intermediate result into the second type data.

Article A33. The method of article A32, where converting the first type data into the intermediate result includes: generating a transition sign bit (Tsign), a transition data bit (Tdata), and a transition exponent bit (Tshift) according to the first type data and the descriptive information; and generating the intermediate result according to the transition sign bit (Tsign), the transition data bit (Tdata), and the transition exponent bit (Tshift).

Article A34. The method of article A32 or article A33, where the intermediate result includes an intermediate data bit (ABS), an intermediate sign bit (SIGN), and an intermediate exponent bit (EXP), and generating the intermediate result according to the transition sign bit (Tsign), the transition data bit (Tdata), and the transition exponent bit (Tshift) includes: calculating the intermediate data bit (ABS) according to the transition data bit (Tdata); calculating the intermediate exponent bit (EXP) according to the the transition exponent bit (Tshift); and calculating the intermediate sign bit (SIGN) according to the transition sign bit (Tsign).

Article A35. The method of any one of articles A32-A34, where the intermediate result further includes an intermediate rounding bit (STK), and generating the intermediate result according to the transition sign bit (Tsign), the transition data bit (Tdata), and the transition exponent bit (Tshift) further includes: calculating the intermediate rounding bit (STK) according to the intermediate data bit (ABS), the intermediate exponent bit (EXP), and the intermediate sign bit (SIGN).

Article A36. The method of any one of articles A32-A35, where the intermediate result further includes the intermediate rounding bit (STK), and generating the intermediate result according to the transition sign bit (Tsign), the transition data bit (Tdata), and the transition exponent bit (Tshift) further includes: calculating the intermediate rounding bit (STK) according to the intermediate data bit (ABS), the intermediate exponent bit (EXP), and the intermediate sign bit (SIGN).

Article A37. The method of any one of articles A32-A36, where calculating the intermediate data bit (ABS) according to the transition data bit (Tdata) includes: judging whether the transition data bit (Tdata) is less than 0; and calculating a complement of the transition data bit and taking the complement of the transition data bit as the intermediate data bit (ABS) if the transition data bit (Tdata) is less than 0, otherwise, taking the transition data bit (Tdata) as the intermediate data bit (ABS).

Article A38. The method of any one of articles A32-A37, where calculating the intermediate data bit (ABS) according to the transition data bit (Tdata) further includes: judging whether a data type of the transition data bit (Tdata) is a first type or a second type; if the data type of the transition data bit (Tdata) is the first type, judging whether the transition data bit (Tdata) is less than 0; if the transition data bit (Tdata) is less than 0, calculating the complement of the transition data bit and taking the complement of the transition data bit as the intermediate data bit (ABS), otherwise, taking the transition data bit (Tdata) as the intermediate data bit (ABS); and if the data type of the transition data bit (Tdata) is the second type, normalizing the transition data bit (Tdata) and taking the normalized transition data bit as the intermediate data bit (ABS).

Article A39. The method of any one of articles A32-A38, where the intermediate exponent bit (EXP) is equal to the transition exponent bit (Tshift).

Article A40. The method of any one of articles A32-A39, where calculating the intermediate rounding bit (STK) is implemented by an and-or logic.

Article A41. The method of any one of articles A32-A40, where receiving the first type data and the descriptive information about the first type data and the second type data includes: determining the number of first type data received and concatenating the first type data to form first concatenation data, and converting the first concatenation data into the intermediate result.

Article A42. The method of any one of articles A32-A41, where the number of first type data received is determined by: by a preset first fixed value, or by the number of processing bits of the converter used in the method, dividing the number of bits of data with the highest number of bits in the first type data and the second type data.

Article A43. The method of any one of articles A32-A42, where receiving the first type data and the descriptive information about the first type data and the second type data includes: determine the number of to-be-split first type data received and split the first type data into split data with the same number, and converting the split data into the intermediate result.

Article A44. The method of any one of articles A32-A43, where the number of to-be-split first type data received is determined by: by a preset second fixed value, or by the number of bits of data with the highest number of bits in the first type data and the second type data, dividing the number of processing bits of the converter used in the method.

Article A45. The method of any one of articles A32-A44, where the descriptive information includes: first descriptive information configured to describe a data type of the first type data and a first exponent bit of the first type data; and second descriptive information configured to describe a data type of the second type data and a second exponent bit of the second type data, where the transition exponent bit (Tshift) is equal to a difference between the first exponent bit and the second exponent bit.

Article A46. The method of any one of articles A32-A45, where the descriptive information includes: the first data type of the first type data; the second data type of the second type data; and a difference exponent bit configured to indicate a difference between the first exponent bit of the first type data and the second exponent bit of the second type data, where the transition exponent bit (Tshift) is equal to the difference exponent bit.

Article A47. The method of any one of articles A32-A46, where the descriptive information further includes a rounding type, where the rounding type includes at least one of the followings: a TO_ZERO, an OFF_ZERO, an UP, a DOWN, a ROUNDING_OFF_ZERO, a ROUNDING_TO_EVEN, and a random rounding.

Article A48. The method of any one of articles A32-A47, where converting the intermediate result into the second type data includes: generating the second type data according to the intermediate data bit (ABS), the intermediate sign bit (SIGN), the intermediate exponent bit (EXP), and the intermediate rounding bit (STK).

Article A49. The method of any one of articles A32-A48, where converting the intermediate result into the second type data includes: calculating a pre-output data bit (Pdata) and a pre-output sign bit (Psign) according to the intermediate data bit (ABS), the intermediate sign bit (SIGN), the intermediate exponent bit (EXP), and the intermediate rounding bit (STK); and generating the second type data according to the pre-output data bit (Pdata) and the pre-output sign bit (Psign).

Article A50. The method of any one of articles A32-A49, where calculating the pre-output d data bit (Pdata) and the pre-output sign bit (Psign) according to the intermediate data bit (ABS), the intermediate sign bit (SIGN), the intermediate exponent bit (EXP), and the intermediate rounding bit (STK) includes: shifting the intermediate data bit (ABS) by the intermediate exponent bit (EXP) to obtain a shift result; and generating a temporary output data bit (ABS′) according to the shift result and the intermediate rounding bit (STK), where the pre-output sign bit (Psign) is equal to the intermediate sign bit.

Article A51. The method of any one of articles A32-A50, where calculating the pre-output data bit (Pdata) and the pre-output sign bit (Psign) according to the intermediate data bit (ABS), the intermediate sign bit (SIGN), the intermediate exponent bit (EXP), and the intermediate rounding bit (STK) further includes: detecting whether the temporary output data bit (ABS′) is greater than a saturation value; if the temporary output data bit (ABS′) is greater than the saturation value, performing saturation processing on the temporary output data bit (ABS′) to obtain the pre-output data bit (Pdata); and if the temporary output data bit (ABS′) is not greater than the saturation value, outputting the temporary output data bit (ABS′) as the pre-output data bit (Pdata).

Article A52. The method of any one of articles A32-A51, where generating the second type data according to the pre-output data bit (Pdata) and the pre-output sign bit (Psign) includes: receiving the pre-output data bit (Pdata) and the pre-output sign bit (Psign) to generate an output data bit representation (Data_out); and obtaining the second type data according to the output data bit representation (Data_out) and the pre-output sign bit (Psign).

Article A53. The method of any one of articles A32-A52, where generating the second type data according to the pre-output data bit (Pdata) and the pre-output sign bit (Psign) further includes: generating a floating-point number decimal point bit number representation (SHIFT_FP) according to the pre-output data bit (Pdata) and the pre-output sign bit (Psign); and obtaining the second type data according to the output data bit representation (Data_out), the floating-point number decimal point bit number representation (SHIFT_FP), and the pre-output sign bit (Psign).

Article A54. The method of any one of articles A32-A53, where receiving the pre-output data bit (Pdata) and the pre-output sign bit (Psign) to generate the output data bit representation (Data_out) includes: receiving the pre-output data bit (Pdata) and the pre-output sign bit (Psign); if the pre-output sign bit (Psign) is a negative number, calculating a complement for the the pre-output data bit (Pdata); and if the pre-output sign bit (Psign) is a positive number, outputting the pre-output data bit as the output data bit representation (Data_out).

Article A55. The method of any one of articles A32-A54, where receiving the pre-output data bit (Pdata) and the pre-output sign bit (Psign) to generate the output data bit representation (Data_out) further includes: receiving the pre-output data bit (Pdata) and judging whether a data type of the pre-output data bit (Pdata) is the first type or the second type; if the data type of the pre-output data bit (Pdata) is the first type, and if the pre-output sign bit (Psign) is the negative number, calculating the complement for the pre-output data bit (Pdata); if the data type of the pre-output data bit (Pdata) is not the negative number, outputting the pre-output data bit as the output data bit representation (Data_out); and if the data type of the pre-output data bit (Pdata) is the second type, normalizing the pre-output data bit (Pdata) and outputting the normalized pre-output data bit as the output data bit representation (Data_out), where a floating-point number decimal point location determinator is configured to determine a floating-point number decimal point bit number representation (SHIFT_FP) according to an output of a second normalizer.

Article A56. The method of any one of articles A32-A55, further including: receiving constraint information, where the constraint information is used to indicate whether a specific standard is supported, and/or a compiling optimization is supported.

Article A57. The method of any one of articles A32-A56, where the data type of the first type data and the data type of the second type data are scalable.

Article A58. An electronic device, including: one or a plurality of processors; and a memory, where the memory stores computer-executable instructions, and when the computer-executable instructions are executed by the one or the plurality of processors, the electronic device performs the method of any one of articles A32-A57.

Article A59. A computer-readable storage medium, including computer-executable instructions, where, when the computer-executable instructions are executed by one or a plurality of processors, the method of any one of articles A32-A57 is performed.

It is required to be noted that for the sake of conciseness, the foregoing method embodiments are all described as a series of combinations of actions, but those skilled in the art should know that the present disclosure is not limited by the described order of action since some steps may be performed in a different order or simultaneously according to the present disclosure. Secondly, those skilled in the art should also understand that embodiments described in the specification are all optional, and actions and modules involved are not necessarily required for this disclosure.

In the embodiments above, the description of each embodiment has its own emphasis. For a part that is not described in detail in one embodiment, reference may be made to related descriptions in other embodiments.

In several embodiments provided in this disclosure, it should be understood that the disclosed apparatus may be implemented in other ways. For instance, the apparatus embodiments above are merely illustrative. For instance, a division of the units is only a logical function division. In an actual implementation, there may be other manners for the division. For instance, a plurality of units or components may be combined or may be integrated in another system, or some features may be ignored or may not be performed. Additionally, the displayed or discussed mutual coupling or direct coupling or communication connection may be implemented through indirect coupling or communication connection of some interfaces, apparatuses or units, and may be electrical, optical, acoustic, magnetic or other forms.

The units described as separate components may or may not be physically separated. The components shown as units may or may not be physical units. In other words, the components may be located in one place, or may be distributed to a plurality of network units. According to certain requirements, some or all of the units may be selected for realizing purposes of the embodiments of the present disclosure.

Additionally, functional units in each embodiment of the present application may be integrated into one processing unit, or each of the units may exist separately and physically, or two or more units may be integrated into one unit. The integrated unit above may be implemented in the form of hardware or in the form of a software program module.

If the integrated unit is implemented in the form of the software program module and sold or used as an independent product, the integrated unit may be stored in a computer-readable memory. Based on such understanding, if technical solutions of the present disclosure may be embodied in the form of a software product, the software product may be stored in a memory, and the software product may include several instructions used to enable a computer device (which may be a personal computer, a server, or a network device, and the like) to perform all or part of steps of the method of the embodiments of the present disclosure. The foregoing memory may include: a USB flash drive, a read-only memory (ROM), a random access memory (RAM), a mobile hard disk, a magnetic disk, or an optical disc, and other media that may store a program code.

It should be understood that terms such as “first”, “second”, “third”, and “fourth” appear in the claims, the specification, and drawings are used for distinguishing different objects rather than describing a specific order. It should be understood that terms “including” and “comprising” used in the specification and the claims indicate the presence of a feature, an entity, a step, an operation, an element, and/or a component, but do not exclude the existence or addition of one or more other features, entities, steps, operations, elements, components, and/or collections thereof.

It should also be understood that terms used in the specification of the present disclosure are merely intended to describe a specific embodiment rather than to limit the present disclosure. As being used in the specification and the claims of the present disclosure, unless the context clearly indicates otherwise, singular forms such as “a”, “an”, and “the” are intended to include plural forms thereof. It should further be understood that a term “and/or” used in the specification and the claims refers to any and all possible combinations of one or more of relevant listed items and includes these combinations.

As being used in this specification and the claims, a term “if” may be interpreted as “when”, or “once” or “in response to a determination” or “in response to a case where something is detected” depending on the context. Similarly, depending on the context, a clause “if it is determined that” or a clause “if [a described condition or event] is detected” may be interpreted as “once it is determined that”, or “in response to a determination”, or “once [a described condition or event] is detected”, or “in response to a case where [a described condition or event] is detected”.

The above has described the embodiments of the present disclosure in detail. Specific examples have been used in the present disclosure to explain principles and implementations of the present disclosure. The descriptions of the above embodiments are only used to facilitate understanding of the method and core ideas of the present disclosure. Simultaneously, persons of ordinary skill in the art may change or transform specific implementations and application scope of the present disclosure according to ideas of the present disclosure. The changes and transformations shall all fall within the protection scope of the present disclosure. In summary, the content of this specification should not be construed as a limitation on the present disclosure.

What is claimed:

1. A converter for data type conversion, comprising:
a first conversion stage (L1) configured to receive first type data and descriptive information about the first type data and second type data and according to the descriptive information, convert the first type data into an intermediate result; and
a second conversion stage (L2) configured to convert the intermediate result into the second type data.

2. The converter of claim 1, wherein the first conversion stage (L1) comprises a first data parsing unit (P1) and a first computation unit (C1), wherein
the first data parsing unit (P1) is configured to generate a transition sign bit (Tsign), a transition data bit (Tdata), and a transition exponent bit (Tshift) according to the first type data and the descriptive information; and
the first computation unit (C1) is configured to generate the intermediate result according to the transition sign bit (Tsign), the transition data bit (Tdata), and the transition exponent bit (Tshift).

3. The converter of claim 2, wherein the intermediate result comprises an intermediate data bit (ABS), an intermediate sign bit (SIGN), and an intermediate exponent bit (EXP), and the first computation unit (C1) comprises:
an absolute value calculation circuit (C11) configured to calculate the intermediate data bit (ABS) according to the transition data bit (Tdata);
an exponent bit calculation circuit (C12) configured to calculate the intermediate exponent bit (EXP) according to the transition exponent bit (Tshift); and
a sign bit calculation circuit (C13) configured to calculate the intermediate sign bit (SIGN) according to the transition sign bit (Tsign).

4. The converter of claim 3, wherein the intermediate result further comprises an intermediate rounding bit (STK), and the first computation unit (C1) further comprises:
a rounding bit calculation circuit (C14) configured to calculate the intermediate rounding bit (STK) according to the intermediate data bit (ABS) and the intermediate sign bit (SIGN).

5. The converter of claim 3, wherein the intermediate result further comprises an intermediate rounding bit (STK), and the first computation unit (C1) further comprises:
a rounding bit calculation circuit (C14) configured to calculate the intermediate rounding bit (STK) according to the intermediate data bit (ABS), the intermediate exponent bit (EXP), and the intermediate sign bit (SIGN).

6. The converter of claim 3, wherein the absolute value calculation circuit (C11) comprises:
a second selector configured to judge whether the transition data bit (Tdata) is less than 0; and
a first complement calculator configured to calculate a complement of the transition data bit and take the complement of the transition data bit as the intermediate data bit (ABS) if the transition data bit (Tdata) is less than 0, otherwise,
take the transition data bit (Tdata) as the intermediate data bit (ABS).

7. The converter of claim 6, wherein the absolute value calculation circuit (C11) further comprises a first selector and a first normalizer, wherein
the first selector is configured to judge whether a data type of the transition data bit (Tdata) is a first type or a second type;
if the data type of the transition data bit (Tdata) is the first type, the first selector selects the second selector for processing;
if the data type of the transition data bit (Tdata) is the second type, the first selector selects the first normalizer for processing; and
the first normalizer is configured to normalize the transition data bit (Tdata) and take the normalized transition data bit as the intermediate data bit (ABS) if the data type of the transition data bit (Tdata) is the second type.

8. The converter of claim 3, wherein an output of the exponent bit calculation circuit (C12), which is the intermediate exponent bit (EXP), is equal to the transition exponent bit (Tshift).

9. The converter of claim 3, wherein the sign bit calculation circuit (C13) is a straight connection line.

10. The converter of claim 1, wherein the first conversion stage (L1) is further configured to determine the number of first type data received and concatenate the first type data to form first concatenation data, and the first conversion stage (L1) converts the first concatenation data into the intermediate result according to the descriptive information.

11. The converter of claim 10, wherein the number of first type data received is determined by:
by a preset first fixed value, or
by the number of processing bits of the converter, dividing the number of bits of data with the highest number of bits in the first type data and the second type data.

12. The converter of claim 1, wherein the first conversion stage (L1) is further configured to determine the number of to-be-split first type data received and split the first type data into split data with the same number, and the first conversion stage (L1) converts the split data into the intermediate result according to the descriptive information.

13. The converter of claim 12, wherein the number of to-be-split first type data received is determined by:
by a preset second fixed value, or
by the number of bits of data with the highest number of bits in the first type data and the second type data, dividing the number of processing bits of the converter.

14. The converter of claim 1, wherein the descriptive information comprises:
first descriptive information configured to describe a data type of the first type data and a first exponent bit of the first type data;
second descriptive information configured to describe a data type of the second type data and a second exponent bit of the second type data, wherein
the transition exponent bit (Tshift) is equal to a difference between the first exponent bit and the second exponent bit
a first data type of the first type data;
a second data type of the second type data; and
a difference exponent bit configured to indicate a difference between a first exponent bit of the first type data and a second exponent bit of the second type data, wherein
the transition exponent bit (Tshift) is equal to the difference exponent bit.

15. (canceled)

16. The converter of claim 14, wherein the descriptive information further comprises a rounding type, wherein the rounding type comprises at least one of the followings: a TO_ZERO, an OFF_ZERO, an UP, a DOWN, a ROUNDING_OFF_ZERO, a ROUNDING_TO_EVEN, and a random rounding.

17. The converter of claim 3, wherein the second conversion stage (L2) comprises a rounding bit calculation circuit (C14) configured to calculate an intermediate rounding bit (STK) according to the intermediate data bit (ABS) and the intermediate sign bit (SIGN).

18. The converter of claim 3, wherein the second conversion stage (L2) further comprises a rounding bit calculation circuit (C14) configured to calculate an intermediate rounding bit (STK) according to the intermediate data bit (ABS), the intermediate exponent bit (EXP), and the intermediate sign bit (SIGN).

19. The converter of claim 4, wherein the second conversion stage (L2) is further configured to generate the second type data according to the intermediate data bit (ABS), the intermediate sign bit (SIGN), the intermediate exponent bit (EXP), and the intermediate rounding bit (STK) and
wherein the rounding bit calculation circuit (C14) is implemented by an and-or logic.

20-31. (canceled)

32. A method for data type conversion, comprising:
receiving first type data and descriptive information about the first type data and second type data and according to the descriptive information, converting the first type data into an intermediate result; and
converting the intermediate result into the second type data.

33-59. (canceled)
